(19) United States
(12) Patent Application Publication
(10) Pub. No.: US 2009/0278186 A1
(43) Pub. Date: Nov. 12, 2009

(54) Double Gate Transistor and Method of Manufacturing Same

(75) Inventors: Jan Sonsky, Leuven (BE); Michiel J. Van Duuren, Valkenswaard (NL)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 12/304,388

(22) PCT Filed: Jun. 6, 2007
(86) PCT No.: PCT/IB07/52128

§ 371 Date: Dec. 11, 2008

(30) Foreign Application Priority Data
Jun. 13, 2006 (EP) 06115400.1

(51) Int. Cl. H01L 29/788; H01L 21/336

(52) U.S. Cl. 257/316; 438/211; 257/E29.3; 257/E21.422

(57) ABSTRACT

A double gate transistor on a semiconductor substrate (2) includes a first diffusion region (S2), a second diffusion region (S3), and a double gate (FG, CG). The first and second diffusion regions (S2, S3) are arranged in the substrate spaced by a channel region (CR). The double gate includes a first gate electrode (FG) and a second gate electrode (CG). The first gate electrode is separated from the second gate electrode by an interpoly dielectric layer (IPD). The first gate electrode is arranged above the channel region and is separated from the channel region by a gate oxide layer (G). The second gate electrode is shaped as a central body. The interpoly dielectric layer is arranged as a conduit-shaped layer surrounding an external surface (A1) of the body of the second gate electrode. The interpoly dielectric layer is surrounded by the first gate electrode.

### FIELD OF THE INVENTION

The present invention relates to a double gate transistor. Also, the present invention relates to a method for manufacturing such a double gate transistor. Moreover, the present invention relates to a non-volatile memory cell comprising such a double gate transistor. Furthermore, the present invention relates to a semiconductor device comprising at least one such non-volatile memory cell.

### BACKGROUND OF THE INVENTION

Non-volatile memory devices (NVMs) are popular and irreplaceable components of virtually any portable electronic apparatus (appliance). The NVM is typically embedded as a process option to baseline logic CMOS platforms. One prior art NVM is the floating gate concept, wherein the floating gate is separated from the control gate by a dielectric layer (inter-poly-dielectric, IPD). A particular embodiment of such a memory is the 2-transistor (2T) cell, where every cell has an access (or selection) gate adjacent to the stacked control gate and floating gate.

By providing a given voltage on the control gate, the control gate is capable of controlling program and erase operations on the floating gate by means of electron tunneling between the substrate and the floating gate.

Typically, in present NVM devices of the type as described above the programming/erasure voltage is about 15-20 V.

Such a voltage level for program and erase has a disadvantage in that portable applications are powered by low voltage batteries so that the high voltage has to be generated and handled on-chip, which consumes area and power. Therefore, portable applications would benefit from a reduction of the voltage level for programming and erasure. This would lead to a reduction of power consumption of the portable applications and, in consequence, would lead to a design of the application that may reduce the required quantity and/or capacity of batteries, or alternatively, to a longer operating time before recharging/replacing batteries. It would furthermore simplify the design of the peripheral driving electronics which need to withstand the otherwise high voltages, thus making it possible to manufacture the flash memory at lower cost, reduced area, mask count, or process complexity (i.e., better yield).

Such reduction of programming/erasing voltages has been previously realized by improving the capacitive coupling between the control gate and the floating gate, either by increasing the area of the floating and control gate overlap or by introducing higher-K dielectric as IPD in between the floating and control gates. The former solution leads to undesirable increase in memory cell size, whereas the latter presents serious manufacturing challenges, so far accompanied with unsatisfactory reliability performance.

### SUMMARY OF THE INVENTION

It is therefore an object of the present invention to provide a double gate transistor which requires lower voltage levels for programming and erasure.

The object of the present invention is achieved by a double gate transistor on a semiconductor substrate, the substrate comprising a first diffusion region, a second diffusion region, and a double gate; the first and second diffusion regions being arranged in the substrate spaced by a channel region; the double gate comprising a first gate electrode and a second gate electrode; the first gate electrode being separated from the second gate electrode by an inter dielectric layer; the first gate electrode being arranged above the channel region and being separated from the channel region by a gate oxide layer;

the second gate electrode being shaped as a central body; the interpoly dielectric layer being arranged as a conduit-shaped layer surrounding an external surface of the body of the second gate electrode, and the interpoly dielectric layer being surrounded by the first gate electrode.

Advantageously, the arrangement of the floating gate surrounding the control gate results in a relatively high coupling between the floating gate and the control gate. By providing such a coupling the voltage on the control gate for programming and erasure can be reduced in comparison to the voltage level as used in the prior art.

Moreover, by such a reduction of the program and erase voltage level, auxiliary circuitry, for instance the charge pump used for increasing the supply voltage level to the voltage level for programming and erasure, can be implemented more simply. This may reduce the number of processing steps for manufacturing a semiconductor device which comprises a non-volatile memory cell according to the present invention and may also save on area of the semiconductor device that is occupied by the memory cell.

Also, the present invention relates to a double gate transistor as described above, wherein the double gate is arranged within a cavity bounded by side walls and upper wall of a pre-metal dielectric layer.

In this manner the present invention advantageously allows creation of non-volatile memory cells in baseline CMOS technologies without affecting any existing CMOS transistors that are covered by the pre-metal dielectric layer.

Also, the present invention relates to a double gate transistor as described above, wherein the cavity comprises at least one opening to the level of a top surface of the pre-metal dielectric layer; the at least one opening being filled with a conductive material arranged for electrical connection of the second gate electrode.

Advantageously, the opening filled with the conductive material may be used for electrical connection of the second gate line. This may lead to a reduction of the number of straps required in a memory array comprising a memory cell of the present invention.

Also, the present invention relates to a method for manufacturing such a double gate transistor on a semiconductor substrate, comprising a first diffusion region, a second diffusion region, and a double gate; the double gate comprising a first gate electrode and a second gate electrode; the first and second diffusion regions being arranged in the substrate spaced by a channel region; the first gate electrode being arranged above the channel region and being separated from the channel region by a gate oxide layer; and the first gate electrode being separated from the second gate electrode by an inter dielectric layer, the method comprising:

forming on the semiconductor substrate at least one CMOS device with the first and second diffusion area, the channel region, and a single gate; the single gate being arranged on top of the channel region and being separated from the channel region by a gate oxide layer;

depositing a pre-metal dielectric layer over the CMOS device, so as to at least cover the single gate;

removing the single gate under the pre-metal dielectric layer so as to form a cavity in the pre-metal dielectric layer;

creating the double gate in the cavity, the second gate electrode being shaped as a central body; the interpoly dielectric layer being arranged as a conduit-shaped layer surrounding an external surface of the body of the second gate electrode, and the interpoly dielectric layer being surrounded by the first gate electrode.

Advantageously, such a method is fully compatible with processing of CMOS based semiconductor devices. Also, the method may require a reduced number of masks (and mask-based operations) in comparison with the method for manufacturing non-volatile memory cells of the prior art.

Also, the present invention relates to a method of manufacturing a double gate transistor as described above, wherein at least one of the first gate electrode material, the dielectric layer and the second gate electrode material is deposited by a conformal deposition process. Advantageously, this allows a uniform coverage of walls in the cavity by the deposited layer and may thus result in uniform electrical properties of such a layer.

Further, the present invention relates to a method of manufacturing a double gate transistor as described above, wherein the deposition of the first gate electrode material is preceded by:

removal of the gate oxide layer;

either regrowth or re-deposition of the gate oxide.

In consequence, the present invention allows that the oxide composition and thickness under a CMOS transistor made in the baseline CMOS process can be different from the tunnel oxide under the double gate transistor, which offers the possibility of tuning the respective oxide layers independently. This provides another advantage with respect to the prior-art, since for example in prior-art 2T cells, both oxides are identical. The reconstruction of the gate oxide according to the present invention is advantageous for scaling purposes.

Method of manufacturing a double gate transistor as described above, wherein a second pre-metal dielectric layer is deposited over said pre-metal dielectric.

During this step, the second pre-metal dielectric layer is deposited over the first pre-metal dielectric layer 5. This allows a formation (or deposition) of initially only a relatively thin (first) pre-metal dielectric layer (sufficient to cover the gate thickness), in which the openings are made and the floating gate and control gate are created and arranged. Then, such a second pre-metal deposition layer provides that the thickness of first and second pre-metal dielectric layers corresponds to a thickness that is normally used in CMOS-based devices. If the second pre-metal dielectric layer is deposited after a first metallization process (first metal), the second pre-metal dielectric layer further advantageously allows to place wiring in a first metal layer above the memory array without unwanted interconnection of the second gate material inside the openings.

Furthermore, the present invention relates to a non-volatile memory cell on a semiconductor substrate comprising a double gate transistor as described above.

In addition, the present invention relates to a semiconductor device comprising at least one double gate transistor as described above.

### BRIEF DESCRIPTION OF DRAWINGS

Embodiments of the invention will now be described, by way of example only, with reference to the accompanying schematic drawings in which corresponding reference symbols indicate corresponding parts, and in which:

FIGS. 1a, 1b respectively show a cross-sectional view and a top-view of a non-volatile 2T-memory cell according to the prior art;

FIGS. 2a, 2b respectively show a cross-sectional view and a top-view of a non-volatile 2T-memory cell according to the present invention;

FIGS. 3a, 3b show a cross-sectional view of the non-volatile 2T-memory cell according to the present invention after an initial standard baseline CMOS fabrication process along line A-A and line B-B respectively;

FIGS. 4a, 4b show a cross-sectional view of the non-volatile 2T-memory cell after a first manufacturing step of the present invention along line A-A and line B-B respectively;

FIGS. 5a, 5b, 5c show a cross-sectional view of the non-volatile 2T-memory cell after a second manufacturing step of the present invention along line A-A, along line B-B and along line C-C, respectively;

FIGS. 6a, 6b, 6c show a cross-sectional view of the non-volatile 2T-memory cell after a third manufacturing step of the present invention along line A-A, along line B-B and along line C-C, respectively;

FIGS. 7a, 7b, 7c show a cross-sectional view of the non-volatile 2T-memory cell after a fourth manufacturing step of the present invention along line A-A, along line B-B and along line C-C, respectively;

FIGS. 8a, 8b, 8c show a cross-sectional view of the non-volatile 2T-memory cell after a fifth manufacturing step of the present invention along line A-A, along line B-B and along line C-C, respectively;

FIGS. 9a, 9b, 9c show a cross-sectional view of the non-volatile 2T-memory cell after a sixth manufacturing step of the present invention along line A-A, along line B-B and along line C-C, respectively, and

FIGS. 10a, 10b, 10c show a cross-sectional view of the non-volatile 2T-memory cell after a subsequent manufacturing step of the present invention along line A-A, line B-B and line C-C, respectively.

### DESCRIPTION OF EMBODIMENTS

The present invention will now be illustrated, by way of a non-limiting example, as an implementation of a non-volatile 2T-memory cell. It is noted, however, that generally the present invention relates to a double gate transistor arrangement which can be used in many types of non-volatile memory cells which can be arranged in for example a 1T NOR, NAND or AND memory array.

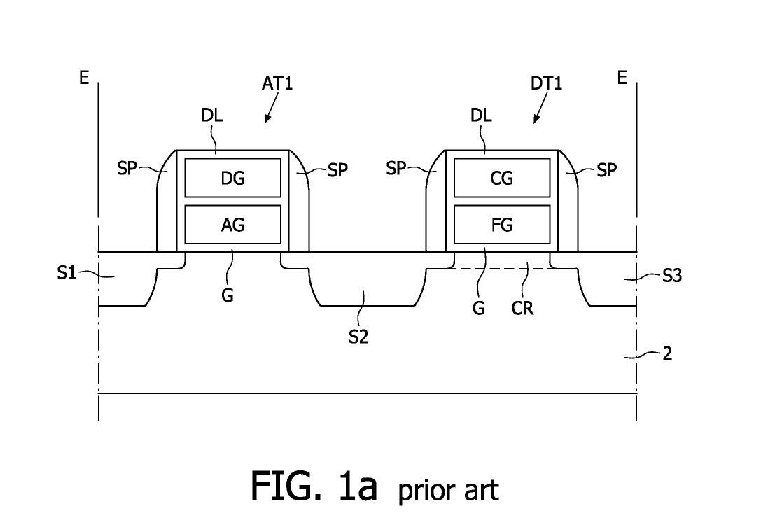

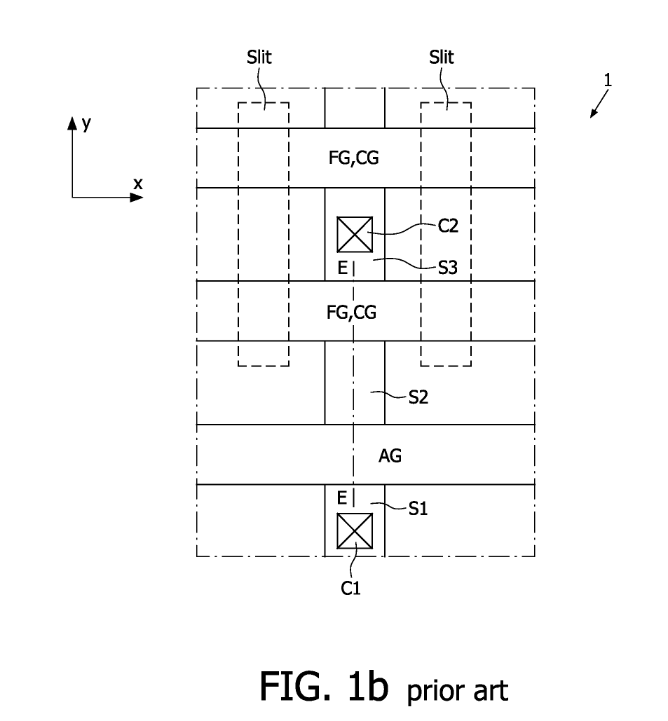

FIGS. 1a, 1b respectively show a cross-sectional view and a top-view of the non-volatile 2T-memory cell according to the prior art.

As shown in cross-section E-E of FIG. 1a, the non-volatile 2T-memory cell 1 of the prior art comprises a semiconductor substrate 2 on a top surface of which an access transistor AT1 and a stacked gate transistor DT1 are located adjacently.

The access transistor AT1 consists of a stack comprising a gate oxide G, an access gate AG, a dummy gate DG, an interpoly dielectric IPD and spacers SP.

In the access transistor AT1, the gate oxide G is arranged on the surface of the semiconductor substrate 2.

On top of the gate oxide G, the access gate AG is arranged, on top of which the interpoly dielectric IPD is arranged. On top of the IPD layer the dummy gate DG is located which has a dummy function in this case (i.e., electrical contacts are made to the AG layer). Finally, the dummy gate DG is covered by a dielectric layer DL which also covers the side walls of the access gate AG and the dummy gate DG. Adjacent to the dielectric DL on the side walls of the access gate AG and the dummy gate DG spacers SP are arranged.

The stacked gate transistor DT1 from the prior art consists of a stack comprising a gate oxide G, a floating gate FG, an interpoly dielectric IPD, a control gate CG and spacers SP.

The tunnel oxide G of the stacked gate transistor is arranged on the surface of the semiconductor substrate 2.

On top of the tunnel oxide G, the floating gate FG is arranged, on top of which the interpoly dielectric IPD is arranged. On top of the IPD layer the control gate CG is located. The control gate CG is covered by a dielectric layer DL which also covers the side walls of the floating gate FG and the control gate CG. Adjacent to the dielectric DL on the side walls of the floating gate FG and the control gate CG spacers SP are arranged.

In between the access transistor AT1 and the stacked gate transistor DT1 a common diffusion region S2 is located. Also, a diffusion region S1 is located in the semiconductor substrate surface on the lateral opposite side of the access transistor AT1 and a diffusion region S3 is located in the semiconductor substrate surface on the lateral opposite side of the double gate transistor DT1.

Persons skilled in the art will appreciate that a diffusion region in a semiconductor substrate may act as either source or drain.

FIG. 1b shows a top view of the layout of a non-volatile 2T-memory cell of the prior art.

The access gate AG is arranged as a line, which extends in the horizontal direction X. The control gate CG is also arranged as a line parallel to the access gate line AG. The floating gate FG extends as a horizontal line below the control gate, but as will be appreciated by the skilled person, is interrupted by slits, indicated by the dashed line rectangle SLIT, to isolate the floating gates FG of the adjacent cells of the 2T-memory array (not shown).

On diffusion region S1, a first contact C1 is arranged. On diffusion region S3, a second contact C2 is arranged. Alternatively, contacts C1 can be formed with Local Interconnect Lines (LIL) in the X-direction (not shown).

In the arrangement of FIGS. 1a, 1b, by providing a given voltage on the control gate CG, the control gate CG is capable of controlling program and erase operations on the floating gate FG.

Under the control of a positive voltage at the control gate CG, electrons can pass the dielectric gate oxide layer G, and can enter into the floating gate as stored electric charge. This process of charge storage on the floating gate can be based on a mechanism of hot-electron injection or Fowler-Nordheim (FN) tunneling (2T, NAND, AND generally use Fowler-Nordheim tunneling, 1T NOR usually uses channel hot electron injection). In a similar way, a sufficiently large negative voltage on the control gate CG can remove the charge stored in the floating gate by FN-tunneling.

Typically, in prior art non-volatile 2T-memory cells as shown in FIGS. 1a, 1b. the programming/erasure voltage is within a range of about 15-20 V.

As mentioned above, such a programming/erasure voltage level may adversely affect the application of non-volatile memory cells in portable applications because of the relatively large power consumption.

The voltage levels for programming and erasure are determined by a coupling factor between the floating gate and the control gate. The coupling factor depends on properties of the IPD layer and of the overlapping area of floating gate and control gate.

In the present invention it is recognized that by improving the coupling factor between floating gate FG and control gate CG, the programming/erasure voltage may be reduced. But such an increase in coupling is only beneficial if it is achieved without increasing the cell size. Advantageously, this will result in a lower power consumption to operate the 2T-memory cell.

It is recognized that the coupling factor can also be improved by replacing the IPD layer material with a high-K material. However, improving the coupling factor in this way may have a drawback in relation to reliability issues and manufacturability.

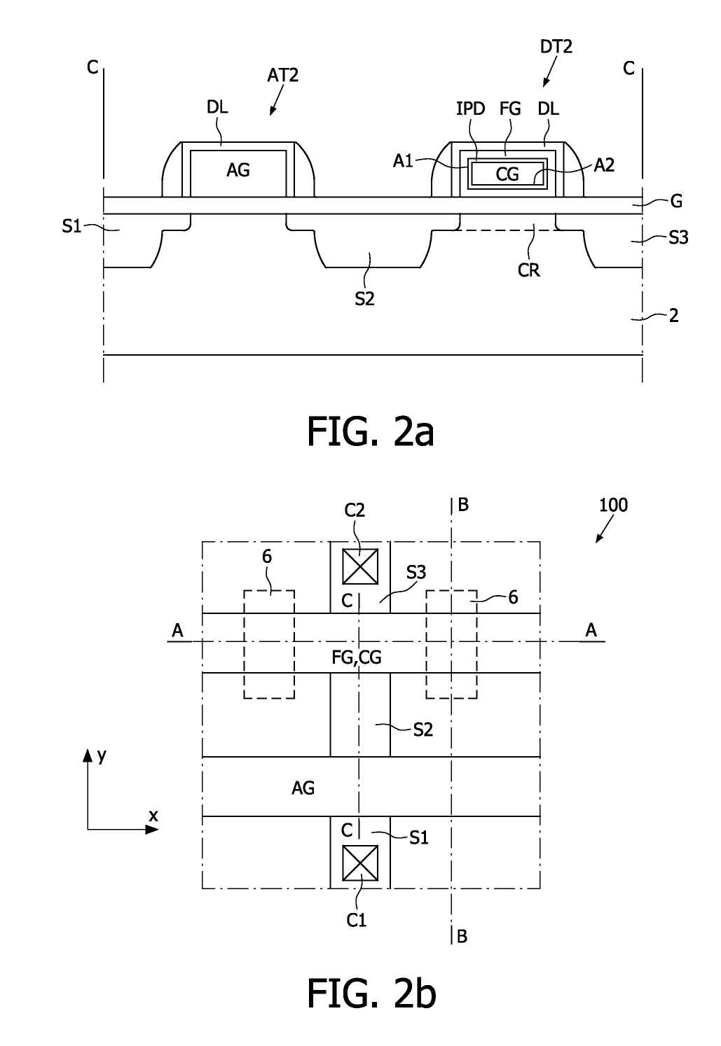

FIGS. 2a, 2b respectively show a cross-sectional view and a top-view of a non-volatile 2T-memory cell according to the present invention.

As shown in cross-section C-C of FIG. 2a, the non-volatile 2T-memory cell 100 according to the present invention comprises a semiconductor substrate 2 on a surface of which a double gate transistor DT2 is located adjacent to an access transistor AT2.

The access transistor AT2 consists of a stack comprising a gate oxide G, an access gate AG, and spacers SP.

In the access transistor AT2, the gate oxide G is arranged on the surface of the semiconductor substrate 2.

On top of the gate oxide G, the access gate AG is arranged, which is covered by a dielectric layer DL (but not indicated in FIG. 2a) which also covers the side walls of the access gate AG. Adjacent to the dielectric DL on the side walls of the access gate AG spacers SP are arranged.

The double gate transistor DT2 of the present invention consists of a gate oxide (tunnel oxide) G, a first gate FG, an interpoly dielectric IPD, a second gate CG and spacers SP.

In this example the first gate electrode FG acts as a floating gate, the second gate electrode CG acts as a control gate.

Again, the gate oxide G is arranged on the surface of the semiconductor substrate 2.

The double gate consists of the second gate CG as a central (rectangular) body. On the external surface of the second gate the interpoly dielectric layer IPD is arranged as a rectangular conduit-shaped layer. The interpoly dielectric layer IPD is surrounded by the first gate which also has a shape of a rectangular conduit. The first gate FG abuts the gate oxide G.

On top of the gate oxide G, the first gate FG is arranged, which has the shape of a rectangular conduit with a first internal surface A1. The first internal surface A1 is typically a closed surface. On the first internal surface A1 the interpoly dielectric IPD layer is arranged. The interpoly dielectric layer IPD also forms a conduit with a second (closed) internal surface A2. Within the area demarcated by the IPD layer the second gate CG is arranged as an inlay. The second gate CG fills the area demarcated by the IPD layer.

The external top surface of the first gate FG is covered by the dielectric layer DL, which also covers the external side walls of the first gate FG. Adjacent to the dielectric DL on the external side walls of the first gate FG spacers SP are arranged.

In between the access transistor AT2 and the double gate transistor DT2 a common diffusion region (diffusion area) S2 is located. Also, a diffusion region S1 is located in the semiconductor substrate surface on the lateral opposite side of the access transistor AT2 and a diffusion region S3 is located in the semiconductor substrate surface on the lateral opposite side of the double gate transistor DT2.

In the double gate transistor DT2 of the 2T-memory cell of the present invention, the first gate FG is arranged to surround the second gate CG fully. In this manner, it is achieved that the coupling area between first gate FG and control gate CG is relatively enlarged in comparison with the coupling area of the floating gate and control gate of the double gate transistor of the prior art. By this arrangement of second gate CG and first gate FG a relatively higher electrical coupling between first gate FG and second gate CG can be achieved than in the stack of the floating gate and the control gate according to the prior art without increasing the cell size.

Ideally, the coupling between first gate FG and second gate CG can be unity, in which case the minimal programming/erasure voltage would be reached. For a nominal thickness of 10 nm of the gate oxide G, the ideal programming/erasure voltage would then be about 10 V, corresponding to an electric field of 10 MV/cm in the tunnel oxide.

It is estimated that in practice, the coupling will be less than unity, and that the programming/erasure voltage in the 2T-memory cell according to the present invention will be between about 11 V and about 13 V, at least below a value as obtained by the 2T-memory cell of the prior art (which typically will be about 15-16 V). Note that actual values of voltages may depend on the cell size and geometry.

FIG. 2b shows a top view of the layout of a non-volatile 2T-memory cell according to the present invention.

The access gate AG is arranged as a line, which extends in the horizontal direction X. The first gate FG and the second gate CG (inside the surrounding first gate FG) is also arranged as a line parallel to the access gate line AG. As will be explained in more detail below, the line of the first gate FG is interrupted between adjacent 2T-memory cells by a hole structure, indicated by the dashed line rectangle HOLE, to isolate the first gates FG of adjacent cells of the 2T memory array (not shown). The second gate CG continues as an uninterrupted line.

On the diffusion region S1, a first contact C1 is arranged. On the diffusion region S3, a second contact C2 is arranged. Again, it is noted that instead of the first contact, an LIL line (not shown) could be used.

Moreover, FIG. 2b shows schematically line A-A parallel with the line of the first gate FG and the second gate CG. A line B-B is shown which extends in the Y-direction and which crosses the HOLE region. Further, line C-C is shown which extends in the Y-direction and which coincides with the direction of the cross-section of FIG. 2a.

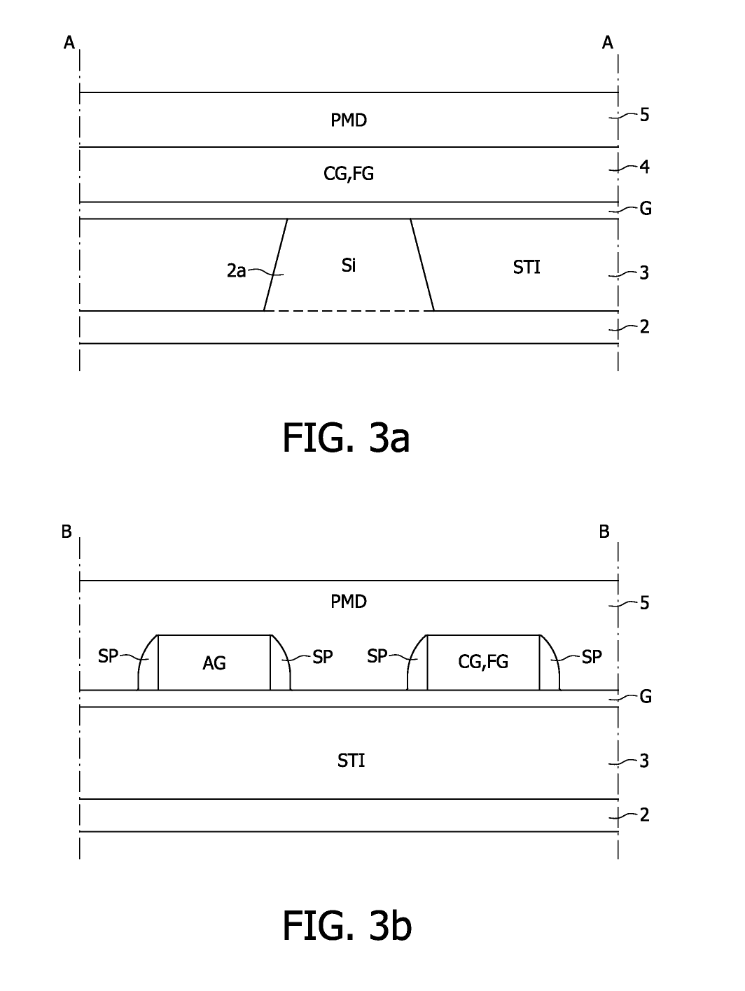

FIGS. 3a, 3b show a cross-sectional view of the non-volatile 2T-memory cell of the present invention after the complete standard front-end-of-line CMOS processing has been completed (up to and including deposition of pre-metal dielectric PMD layer and its planarization using e.g. chemical mechanical polishing CMP process) along line A-A and along line B-B respectively. The following Figures will illustrate the sequence of unique manufacturing steps resulting in fabrication of a device according to the present invention.

The manufacturing of the non-volatile 2T-memory cell 100 according to the present invention, follows the fabrication during a standard baseline digital CMOS process up to the process of the pre-metal dielectric (PMD) so as to form at least one CMOS device with a first and second diffusion area S2, S3, a channel region CR, a single gate CG/FG, and spacers SP.

The channel region CR is arranged in between the first and second diffusion areas S2, S3. The single gate CG/FG is arranged on top of the channel region CR, and is separated from the channel region CR by the gate oxide layer G. The single gate CG/FG comprises side walls which are covered by spacers SP. A pre-metal dielectric layer 5 which is typically a planarised dielectric layer covers the CMOS device.

In the case of the example of a 2T-memory cell, two adjacent CMOS devices that share a common diffusion area are formed by such a standard baseline digital CMOS process as is explained in more detail below.

At the surface of the semiconductor substrate 2, isolation regions 3 (for example STI or shallow trench isolation regions) are defined, which isolate a portion of the semiconductor surface 2a. Then n-type and p-type wells are implanted. On top of the isolated semiconductor substrate portion 2a, the gate oxide G is formed.

Next, a poly-Si layer 4 is deposited. The poly-Si layer 4 is patterned to form an access gate line AG and a (single) gate line CG/FG. After patterning the lines AG and CG/FG, spacers are created on the side walls of the lines AG and CG/FG.

Simultaneously, the gates in other parts of the circuitry e.g. logic are patterned. Next n-type and p-type extensions and possibly halos (pockets) are implanted using dedicated masks and non-conducting spacers are created on the side walls of each gate including the lines AG and CG/FG.

Next, the n++ and p++source and drains are implanted to form NMOS and PMOS transistors, respectively, and silicided (these details are not shown).

The lines CG/FG are preferably excluded from silicidation in the present invention.

Finally, the a pre-metal dielectric (PMD) layer 5 is deposited and planarised. FIGS. 3a and 3b show the 2T-memory cell at this processing stage. The pre-metal dielectric layer 5 typically consists of oxide with a thickness between 200 and 700 nm. It may also be composed of a multilayer including a thin 10-30 nm silicon nitride or silicon carbide layer and a thick 200-700 nm silicon oxide layer.

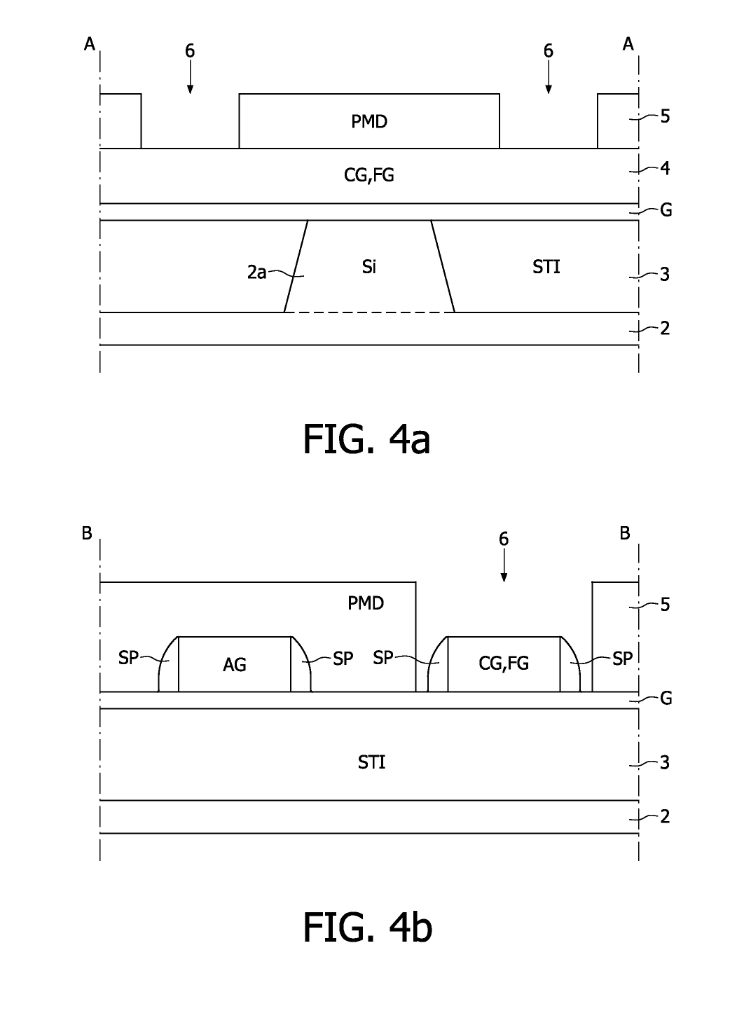

It is noted that for reasons of clarity in the FIGS. 4-9 the diffusion areas S1, S2, S3 are not shown.

FIGS. 4a, 4b show a cross-sectional view of the non-volatile 2T-memory cell of the present invention after a first manufacturing step along line A-A and line B-B respectively.

During this first manufacturing step, openings 6 are etched in the pre-metal dielectric layer 5, by using a lithographic process with a mask that comprises pattern elements HOLE as indicated in FIG. 2b. The width of the pattern elements HOLE (in the Y-direction) is somewhat larger than the width of the CG/FG line. The etching process is carried out in such a way that the pre-metal dielectric (PMD) layer 5 is removed above the CG/FG line in the opening 6 defined by the HOLE mask using photoresist as a masking layer. This anisotropic etch will typically remove only the PMD layer material from above the CG/FG line and its surroundings and stop etching on the gate CG/FG poly-silicon layer.

It is noted that the process to form openings 6 may be tuned in such a way that the openings 6 become tapered (somewhat wider at the surface than at the interface with the gate CG/FG poly-silicon layer), as the tapered shape may ease the execution of further manufacturing steps (see below).

The access gate AG is protected by the pre-metal dielectric layer 5 from becoming a double-gate transistor.

It is noted that in this manner the present invention advantageously allows creation of non-volatile memory cells in baseline CMOS technologies without affecting any existing CMOS transistors that are covered by the pre-metal dielectric layer.

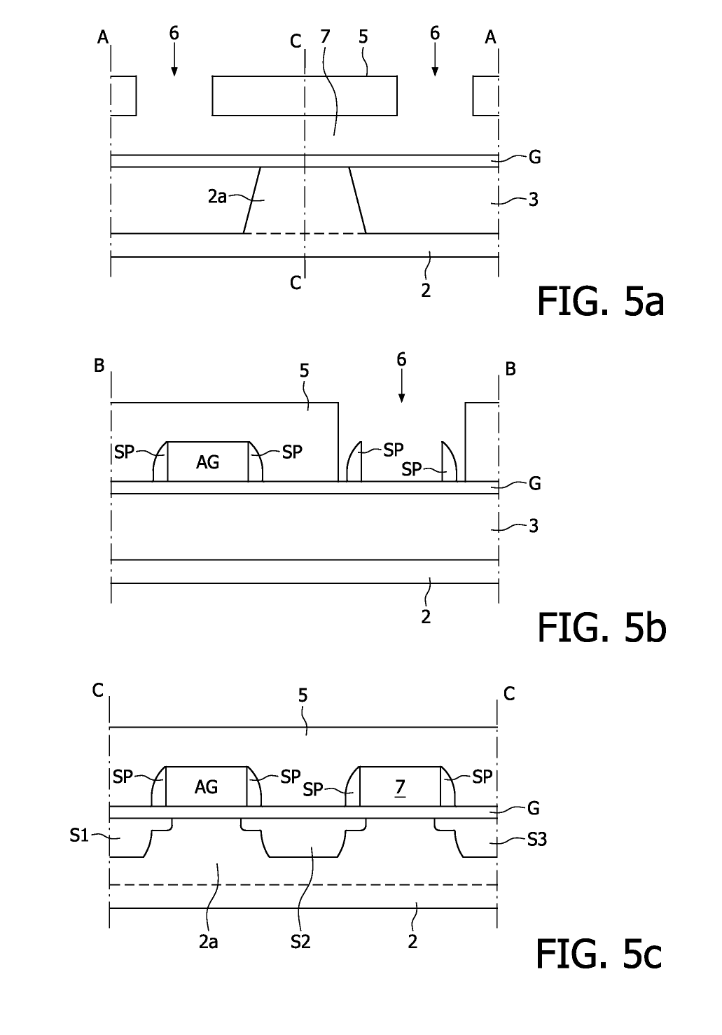

FIGS. 5a, 5b, 5c show a cross-sectional view of the non-volatile 2T-memory cell of the present invention after a second manufacturing step along line A-A, along line B-B and along line C-C, respectively.

During this manufacturing step, an isotropic poly-silicon etching process is carried out to remove completely the gate CG/FG lines exposed through the openings 6. The isotropic poly-silicon etching process is selective with respect to silicon dioxide. Such an etching process per se is known in the art. It may be either a wet etching or a dry etching process.

In principle the gate oxide remains intact during the isotropic etching. But since reliability is essential to memories, it may be preferred to remove the original gate oxide by e.g. wet etching and grow or deposit a new gate oxide layer customized for the needs of the memory transistors. The growth or deposition is done in a self-aligned process, via the openings 6, which process thus saves additional mask layers. Also alternative materials such as higher-k dielectric, e.g. hafnium oxide HfO₂, hafnium silicate HfSiO, nitrided hafnium silicate HfSiON, aluminium oxide Al2O3, zirconium oxide, etc. can be used for this gate dielectric, as long as these can be either grown on silicon or deposited in conformity.

In consequence, the oxide composition and thickness under the AG can be different from the tunnel oxide G under DT2, which offers the possibility of tuning the respective oxide layers independently. This provides another advantage over the prior-art, since in prior-art 2T cells, both oxides are identical. This is advantageous for scaling purposes.

By means of the etching process the poly-Si CG/FG line is removed at the location of the openings 6 and also below the pre-metal dielectric layer 5 in between two openings 6 that are adjacent in the X-direction. A continuous tunnel in the pre-metal dielectric layer 5 is formed. The etching time of the isotropic silicon etch should be selected appropriate to the spacing of the openings 6.

By the etching process and the gate oxide regrowth process, a cavity 7 is shaped which is bounded by the surfaces of the gate oxide layer G and the pre-metal dielectric layer 5.

The spacers SP of the CG/FG line are left substantially intact by the etching process.

The access gate line AG is not affected by the etching process due to the isolation by means of the pre-metal dielectric layer 5 that encapsulates the access gate line AG.

FIG. 5c shows a cross-sectional view of the 2T-memory cell at the location of line C-C as shown in FIG. 2b. Above the semiconductor substrate portion 2a (the region 2a indicates a P-well region), the cavity 7 is bounded by side walls and an upper wall of the pre-metal dielectric layer 5. For example, the cavity 7 can have a height between about 50 and 200 nm.

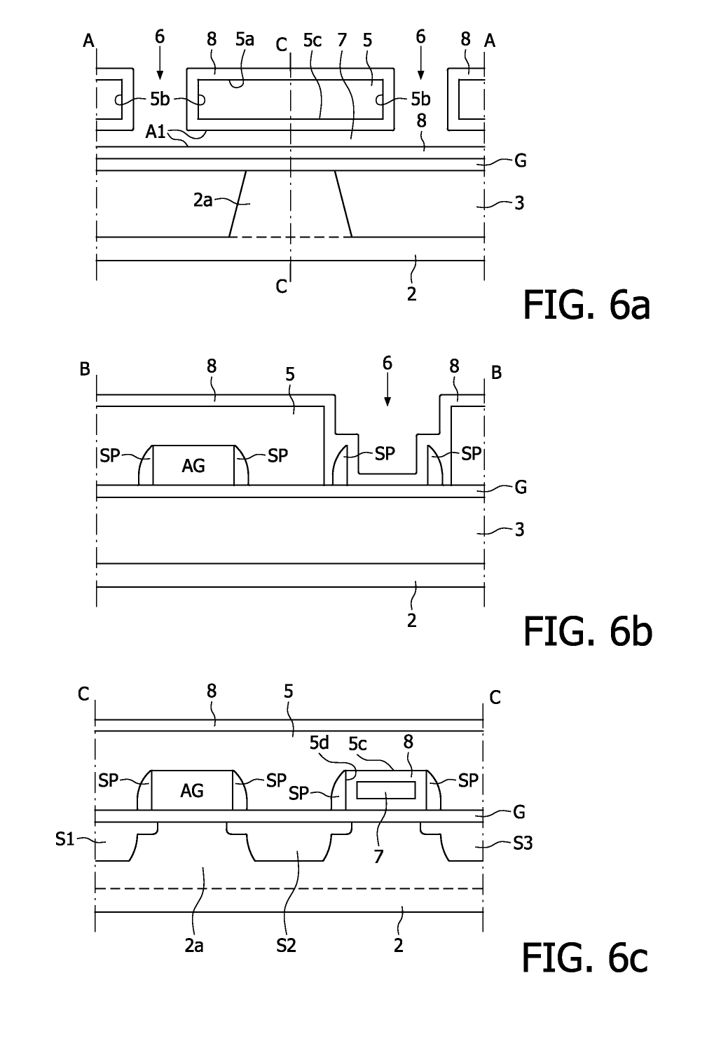

FIGS. 6a, 6b, 6c show a cross-sectional view of the non-volatile 2T-memory cell of the present invention after a third manufacturing step along line A-A, along line B-B and along line C-C, respectively.

During this manufacturing step, a doped poly-Si layer 8 is deposited by means of preferably a chemical vapor deposition process, which allows a conformal deposition of the doped poly-Si layer 8. The doped poly-Si layer 8 covers vertical and horizontal surfaces 5a, 5b, 5c of the pre-metal dielectric layer 5 and of the cavity 7.

The thickness of the doped poly-Si layer 8 can be about 20 nm.

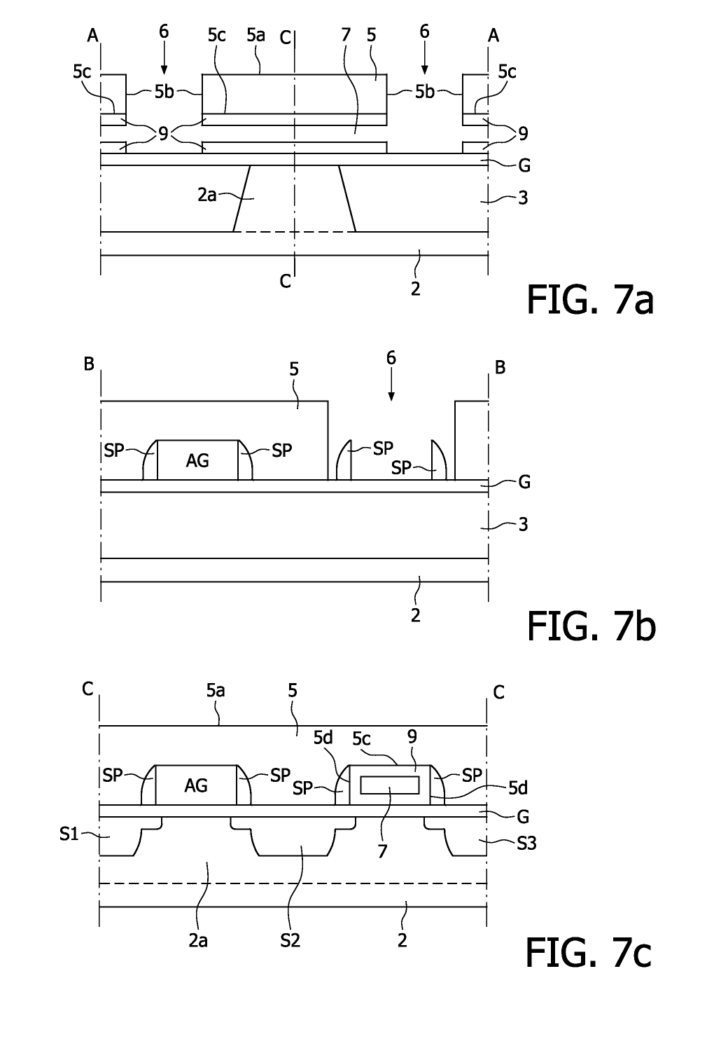

FIGS. 7a, 7b, 7c show a cross-sectional view of the non-volatile 2T-memory cell of the present invention after a fifth manufacturing step along line A-A, along line B-B and along line C-C, respectively.

During this manufacturing step, the doped poly-Si layer 8 is etched by means of an anisotropic etching process.

Due to the anisotropy of the etching process, the poly-Si is removed from the top surfaces 5a and side walls 5b in the openings 6 of the pre-metal dielectric layer 5 and from the horizontal bottom of the openings 6, while the poly-Si layer 9 remains intact on the inward surfaces 5c of the pre-metal dielectric layer 5 and on the surface portions of the gate oxide layer G bounded by (the projection of) the openings 6.

On the upper and side walls 5c, 5d of the cavity 7 the doped poly-Si layer 9 remains intact during this etching as shown in FIG. 7c.

In the openings 6, the doped poly-Si layer 8 is removed by the etching process.

Typically, the etching of the poly-Si layer is performed with an overetch (i.e., etching during a relatively longer time than needed for a given layer thickness and a given etch-rate) to ensure that undesired poly-Si residues (e.g., on the sidewalls of openings 6) are removed and FG gates of adjacent memory cells are disconnected.

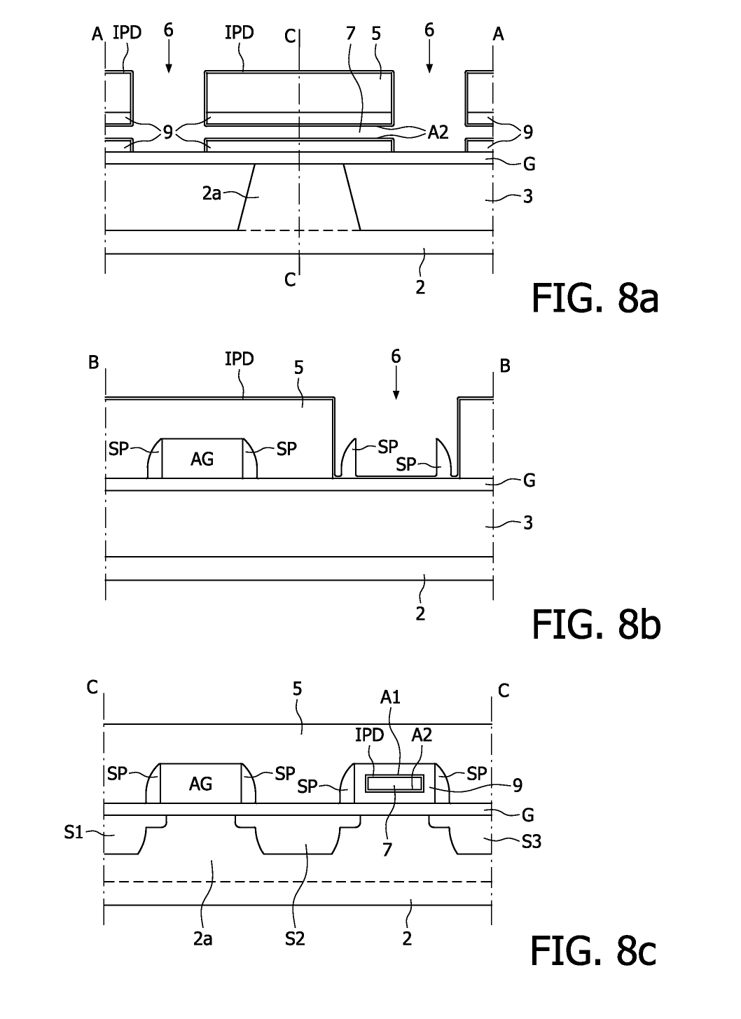

FIGS. 8a, 8b, 8c show a cross-sectional view of the non-volatile 2T-memory cell of the present invention after a sixth manufacturing step along line A-A, along line B-B and along line C-C, respectively.

Next, an inter-poly dielectric layer IPD is deposited by preferably a chemical vapor deposition process which allows a conformal growth of the inter-poly dielectric layer IPD.

The inter-poly dielectric layer IPD covers all exposed vertical and horizontal surfaces 5a, 5b of the pre-metal dielectric layer 5. Also, the inter-poly dielectric layer IPD covers the doped poly-Si layer 9 in the cavity 7 on both the inward surface 5c of the pre-metal dielectric layer 5 and the surface portions of the gate oxide layer G in the cavity bounded by (the projection of) the openings 6.

Moreover, in the openings 6 the side walls of the pre-metal dielectric layer 5, the spacers SP and the gate oxide layer G are also coated by the inter-poly dielectric layer IPD.

The (electrical) thickness of the inter-poly dielectric layer IPD is about 5-15 nm.

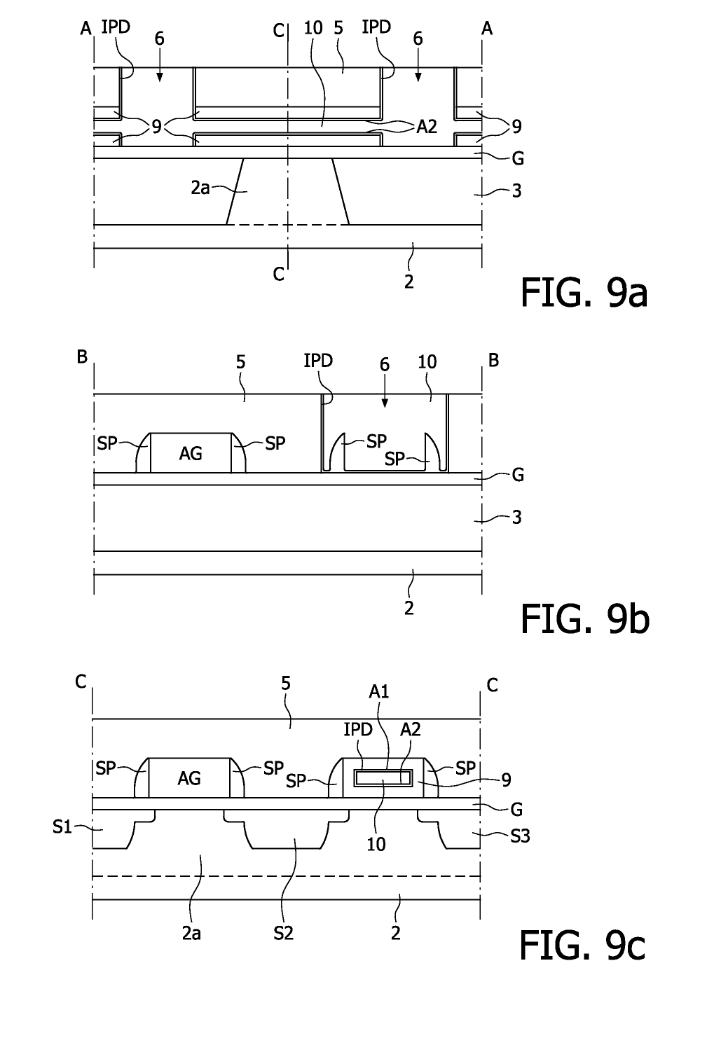

FIGS. 9a, 9b, 9c show a cross-sectional view of the non-volatile 2T-memory cell of the present invention after a sixth manufacturing step along line A-A, along line B-B and along line C-C, respectively.

During this manufacturing step, a deposition of second gate material 10 is carried out. Typically, as appreciated by the skilled person, a chemical vapor deposition process is capable of filling the cavity 7 with the second gate material 10.

Suitable materials for this deposition process are for example doped poly-Si or tungsten.

After deposition of the second gate material 10, a planarization is carried out to remove the second gate material 100 from the top surface of the pre-metal dielectric layer 5. The openings 6 are filled with second gate material 10 to the level of the top surface of the pre-metal dielectric layer 5.

The cavity 7 is completely filled with second gate material 10 and forms a continuous buried line.

Advantageously, the openings 6 filled with second gate material 10 may be used for electrical connection of the second gate line.

Using tungsten as second gate material 10 can result in a lower overall resistance of the second gate, which advantageously may lead to a reduction of the number of straps required in a memory array comprising the 2T-memory cell of the present invention.

Next the usual contact holes are formed in order to connect source (diffusion region), drain (diffusion region), gate, access gate and the control gate CG regions of all circuit elements present on the chip. Further, the manufacturing continues with back-end-of-line (interconnect or wiring) processing in a classical way known to skilled people. So multiple metal layer interconnects can be realized. This will not be described here.

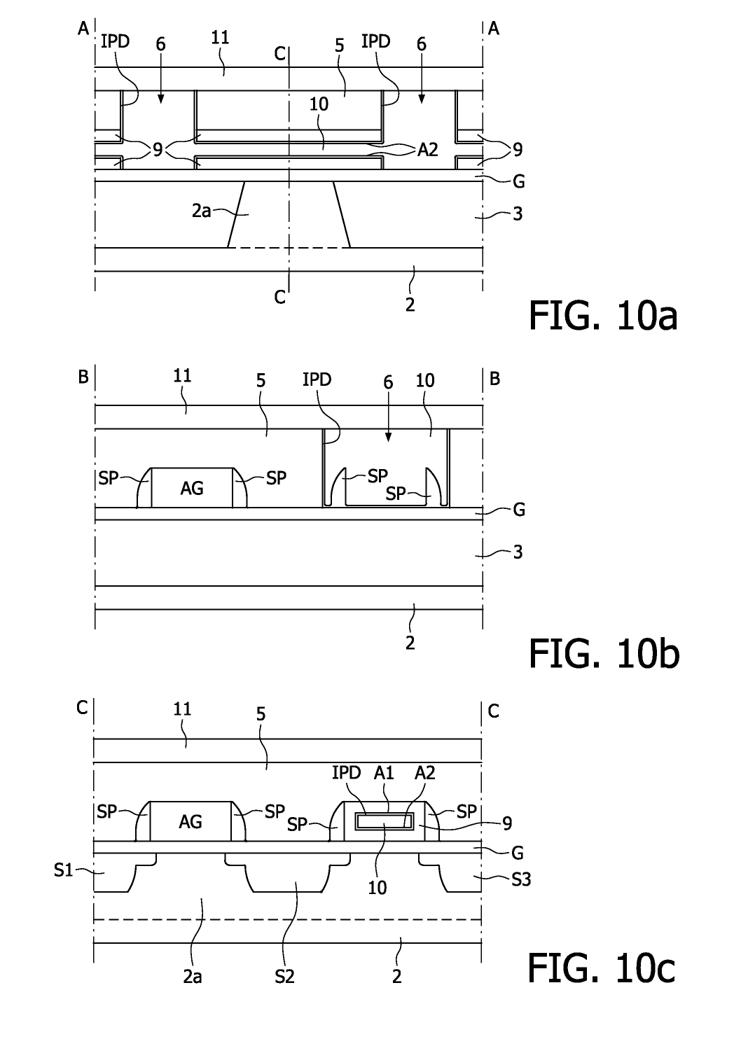

FIGS. 10a, 10b, 10c show a cross-sectional view of the non-volatile 2T-memory cell of the present invention after a subsequent manufacturing step along line A-A, line B-B and line C-C, respectively, according to another embodiment of this invention.

During this step, a second pre-metal dielectric layer 11 may be deposited over the first pre-metal dielectric layer 5. This allows a formation (or deposition) of initially only a relatively thin PMD layer 5 (sufficient to cover the gate thickness, i.e. thickness of PMD of about 100 nm above the gate tops), in which the openings 6 are made and the FG and CG are created and arranged according to the first embodiment of this invention.

Then, such a second pre-metal deposition layer 11 may be needed to ensure that the surface of the 2T-memory cell 100 may substantially correspond to a thickness that is normally used in CMOS-based devices. If the second pre-metal dielectric layer 11 is deposited after a first metallization process (first metal), the second pre-metal dielectric layer 11 further allows to place wiring in a first metal layer above the memory array without unwanted interconnection of the second gate material 10 inside the openings 6 (i.e., these openings are now buried by the second PMD layer 11).

Alternatively, the PMD layer 5 may be used as a dummy layer that would be removed after the double gate structure is formed. In this case, all the implantations (extensions, halos, and diffusion implants) would be done after the formation of the double gate structure, which allows flexibility in processing temperature budget for the materials used to form the CG and/or FG structure. In this case, also the spacers will not be in place, but would be realized after the e.g. wet etch removal of the dummy PMD layer.

It will be apparent to persons skilled in the art that other embodiments of the invention can be conceived and reduced to practice without departing form the true spirit of the invention, the scope of the invention being limited only by the appended claims as finally granted. The description is not intended to limit the invention. In the above description the 2T memory cell configuration is used only as an example.

A variation may be to use the original gate oxide G vs. its removal and replacement with a dedicated gate oxide layer (or generally a gate dielectric layer). Alternative materials may be used as a new gate dielectric, such as silicon nitride or other higher-K materials deposited through e.g. the atomic layer CVD method.

Similarly, the IPD layer may consist of a variety of non-traditional higher-K dielectrics. As the processing steps that will follow are in that case at relatively low temperature, the integration is more straightforward. Furthermore, any undesired re-crystallization of high-K dielectric layers can thus be avoided which may result in better reliability.

The FG and CG gates may be classical doped poly-Si or other conductive materials such as tungsten (deposited by low pressure CVD) or other metals (deposited by atomic layer or low pressure CVD).

Furthermore, the channel doping under the CG/FG transistor may be omitted during the standard well implantations and instead be realized again in a self-aligned way through vapor phase doping or plasma immersion doping techniques (both techniques are well known and allow doping of highly non-conformal surfaces) to incorporate the right amount of dopants (e.g., B, As, P, . . . ) in the transistor channel once the tunnel has been formed and the initial gate oxide G removed. This step would be followed by new gate oxide growth/deposition and identical steps as described in the first embodiment.

1. A double gate transistor on a semiconductor substrate,
comprising a first diffusion region, a second diffusion region, and a double gate;
the first and second diffusion regions being arranged in the substrate spaced by a channel region;
the double gate comprising a first gate electrode and a second gate electrode;
the first gate electrode being separated from the second gate electrode by an inter dielectric layer;
the first gate electrode being arranged above the channel region and being separated from the channel region by a gate oxide layer;
the first gate electrode being arranged as a conduit-shaped layer having a first internal surface surrounding the interpoly dielectric layer,
the interpoly dielectric layer surrounding the second gate electrode, the second gate electrode being shaped as a central body.

2. Double gate transistor according to claim 1, wherein the double gate is arranged in a cavity bounded by side walls and upper wall of a pre-metal dielectric layer.

3. Double gate transistor according to claim 2, wherein the cavity comprises at least one opening (6) to the level of a top surface of the pre-metal dielectric layer; the at least one opening being filled with a conductive material arranged for electrical connection of the second gate electrode.

4. Double gate transistor according to claim 1, wherein the first gate electrode material comprises doped poly-Si.

5. Double gate transistor according to claim 1, wherein the second gate electrode material comprises at least one of poly-Si and Tungsten.

6. Method of manufacturing a double gate transistor on a semiconductor substrate, the substrate comprising a first diffusion region, a second diffusion region, and a double gate; the double gate comprising a first gate electrode and a second gate electrode; the first and second diffusion regions being arranged in the substrate spaced by a channel region; the first gate electrode being arranged above the channel region and being separated from the channel region by a gate oxide layer; and the first gate electrode being separated from the second gate electrode by an inter dielectric layer;
the method comprising:
forming on the semiconductor substrate at least one CMOS device with the first and second diffusion area, the channel region, and a single gate; the single gate being arranged on top of the channel region and being separated from the channel region by a gate oxide layer;
depositing a pre-metal dielectric layer over the CMOS device, so as to at least cover the single gate;
removing the single gate under the pre-metal dielectric layer so as to form a cavity in the pre-metal dielectric layer;
creating the double gate in the cavity, the first gate electrode being arranged as a conduit-shaped layer having a first internal surface (A1) surrounding the interpoly dielectric layer,
the interpoly dielectric layer surrounding the second gate electrode, the second gate electrode being shaped as a central body.

7. Method of manufacturing a double gate transistor according to claim 6, wherein the creation of the double gate in the cavity comprises:
depositing on side walls and upper wall of the cavity the first gate electrode material.

8. Method of manufacturing a double gate transistor according to claim 6, wherein the creation of the double gate in the cavity comprises:
depositing on the first internal surface the interpoly dielectric layer, the dielectric layer having a shape of a conduit with a second internal surface.

9. Method of manufacturing a double gate transistor according to claim 8, wherein the creation of the double gate in the cavity comprises:
depositing on the second internal surface a second gate electrode material so as to form the second gate electrode as the central body.

10. Method of manufacturing a double gate transistor according to claim 6, wherein at least one of the first gate electrode material, the dielectric layer and the second gate electrode material is deposited by a conformal deposition process.

11. Method of manufacturing a double gate transistor according to claim 6, wherein at least one of the first gate electrode material, the dielectric layer and the second gate electrode material is deposited by means of a respective chemical vapor deposition process.

12. Method of manufacturing a double gate transistor according to claim 6, wherein the first gate electrode material comprises doped poly-Si.

13. Method of manufacturing a double gate transistor according to claim 7, wherein the deposition of the first gate electrode material is preceded by:
removal of the gate oxide layer;
either regrowth or re-deposition of the gate oxide.

14. Method of manufacturing a double gate transistor according to claim 6, wherein the removal of the single gate under the pre-metal dielectric layer comprises:
etching at least one opening in the pre-metal dielectric layer, so as to remove the pre-metal dielectric layer above the single gate.

15. Method of manufacturing a double gate transistor according to claim 14, wherein the at least one opening has a tapered shape.

16. Method of manufacturing a double gate transistor according to claim 6, wherein the pre-metal dielectric layer comprises silicon dioxide, and the removal of the single gate under the pre-metal dielectric comprises an isotropic etching process that is selective with respect to silicon dioxide.

17. Method of manufacturing a double gate transistor according to claim 6, wherein a second pre-metal dielectric layer is deposited over said pre-metal dielectric.

18. Non-volatile memory cell on a semiconductor substrate comprising a double gate transistor according to claim 1.

19. Non-volatile memory cell according to claim 18, wherein the non-volatile memory cell further comprises an access transistor.

20. Semiconductor device comprising at least one double gate transistor according to claim 1.
